(19) United States
(12) Patent Application Publication
(10) Pub. No.: US 2024/0234662 A1
(43) Pub. Date: Jul. 11, 2024

(54) DISPLAY DEVICE

(71) Applicant: Samsung Display Co., LTD., Yongin-si (KR)

(72) Inventors: JAEHYUN LEE, Yongin-si (KR); WOOGEUN LEE, Yongin-si (KR); KAP SOO YOON, Yongin-si (KR); HYUNGJIN SONG, Yongin-si (KR); JUNG KYOUNG CHO, Yongin-si (KR); SEUNG-HA CHOI, Yongin-si (KR)

(21) Appl. No.: 18/453,082

(22) Filed: Aug. 21, 2023

(30) Foreign Application Priority Data
Jan. 5, 2023 (KR) 10-2023-0001862

(51) Int. Cl. H01L 33/62; G09G 3/32; H01L 25/075; H01L 25/16; H01L 27/12

(52) U.S. Cl. CPC H01L 33/62; G09G 3/32; H01L 25/0753; H01L 25/167; H01L 27/124; H01L 27/1255; G09G 2310/0267

(57) ABSTRACT

A display device includes: a substrate; a first conductive layer on the substrate and including a lower conductive pattern and a capacitor conductive pattern spaced apart from the lower conductive pattern in a plan view; an active layer on the first conductive layer, partially overlapping the lower conductive pattern and the capacitor conductive pattern in the plan view, and including a driving active pattern defining a storage capacitor together with the capacitor conductive pattern; a second conductive layer on the active layer, partially overlapping the lower conductive pattern and the driving active pattern in the plan view, and including a control pattern defining a driving transistor together with the driving active pattern; and a third conductive layer on the second conductive layer and including an anode electrode partially overlapping the lower conductive pattern in the plan view.

### CROSS-REFERENCED TO RELATED APPLICATION

The present application claims priority to and the benefit of Korean Patent Application No. 10-2023-0001862, filed on Jan. 5, 2023, in the Korean Intellectual Property Office, the entire content of which is incorporated herein by reference.

### BACKGROUND

### 1. Field

Aspects of some embodiments of the present disclosure relate to a display device.

### 2. Description of the Related Art

A display device includes a plurality of pixels, and each pixel includes transistors, capacitors, and light emitting devices. Transistors, capacitors, and light emitting devices are formed from conductive layers. When parasitic capacitance is formed between the conductive layers, display quality of the display device may be degraded. Therefore, research to prevent parasitic capacitance from occurring is ongoing.

The above information disclosed in this Background section is only for enhancement of understanding of the background and therefore the information discussed in this Background section does not necessarily constitute prior art.

### SUMMARY

Aspects of some embodiments include a display device with relatively improved display quality.

A display device according to some embodiments may include a substrate, a first conductive layer on the substrate and including a lower conductive pattern and a capacitor conductive pattern spaced apart from the lower conductive pattern in a plan view, an active layer on the first conductive layer, partially overlapping the lower conductive pattern and the capacitor conductive pattern in a plan view, and including a driving active pattern defining a storage capacitor together with the capacitor conductive pattern, a second conductive layer on the active layer, partially overlapping the lower conductive pattern and the driving active pattern in a plan view, and including a control pattern defining a driving transistor together with the driving active pattern, and a third conductive layer on the second conductive layer and including an anode electrode partially overlapping the lower conductive pattern in a plan view.

According to some embodiments, the control pattern may contact the capacitor conductive pattern.

According to some embodiments, the anode electrode may be spaced apart from at least a portion of the capacitor conductive pattern in a plan view.

According to some embodiments, the anode electrode may contact the driving active pattern.

According to some embodiments, the first conductive layer may further include a driving voltage line extending in a first direction and electrically connected to the driving active pattern, a data line extending in the first direction and spaced apart from the driving voltage line in a second direction crossing the first direction, and an initialization voltage line extending in the first direction and spaced apart from the driving voltage line in a third direction opposite to the second direction.

According to some embodiments, the lower conductive pattern and the capacitor conductive pattern may be located between the driving voltage line and the data line in a plan view.

According to some embodiments, the lower conductive pattern may be located between the driving voltage line and the capacitor conductive pattern in a plan view, and the capacitor conductive pattern may be located between the lower conductive pattern and the data line in a plan view.

According to some embodiments, the active layer may further include a switching active pattern spaced apart from the driving active pattern in a plan view and electrically connected to the data line and an initialization active pattern spaced apart from the driving active pattern in a plan view and electrically connected to the initialization voltage line.

According to some embodiments, the second conductive layer further include a first scan line partially overlapping the switching active pattern in a plan view and a second scan line partially overlapping the initialization active pattern in a plan view.

According to some embodiments, the switching active pattern and the first scan line may define a switching transistor, and the initialization active pattern and the second scan line may define an initialization transistor.

According to some embodiments, the switching transistor may be electrically connected to the capacitor conductive pattern.

According to some embodiments, the display device may further include a fourth conductive layer between the second conductive layer and the third conductive layer and overlapping at least a portion of each of the lower conductive pattern and the capacitor conductive pattern in a plan view.

A display device according to some embodiments may include a substrate, a first conductive layer on the substrate, an active layer on the first conductive layer, a second conductive layer on the active layer, and a third conductive layer on the second conductive layer, and the first conductive layer may include a driving voltage line on the substrate and extending in a first direction, a first data line on the substrate, extending in the first direction, and spaced apart from the driving voltage line in a second direction crossing the first direction, an initialization voltage line on the substrate, extending in the first direction, and spaced apart from the driving voltage line in a third direction opposite to the second direction, first to third lower conductive patterns on the substrate, located between the driving voltage line and the first data line in a plan view, and spaced apart from each other along the first direction, and first to third conductive patterns on the substrate, located between the driving voltage line and the first data line in a plan view, and spaced apart from the first to third lower conductive patterns, and spaced apart from each other along the first direction.

According to some embodiments, the first capacitor conductive pattern may be located between the first lower conductive pattern and the first data line in a plan view, the second capacitor conductive pattern may be located between the second lower conductive pattern and the first data line in a plan view, and the third capacitor conductive pattern may be located between the third lower conductive pattern and the first data line in a plan view.

According to some embodiments, the active layer may include a first driving active pattern partially overlapping the first lower conductive pattern and the first capacitor conductive pattern in a plan view, a second driving active pattern partially overlapping the second lower conductive pattern and the second capacitor conductive pattern in a plan view and spaced apart from the first driving active pattern in the first direction, a third driving active pattern partially overlapping the third lower conductive pattern and the third capacitor conductive pattern in a plan view and spaced apart from the second driving active pattern in the first direction, first to third switching active patterns spaced apart from the first to third driving active patterns in a plan view and spaced apart from each other along the first direction, and first to third initialization active patterns spaced apart from the first to third driving active patterns and the first to third switching active patterns in a plan view and spaced apart from each other along the first direction.

According to some embodiments, the first driving active pattern may define a first storage capacitor together with the first capacitor conductive pattern, the second driving active pattern may define a second storage capacitor together with the second capacitor conductive pattern, and the third driving active pattern may define a third storage capacitor together with the third capacitor conductive pattern.

According to some embodiments, the first to third driving active patterns may be electrically connected to the driving voltage line, and the first to third initialization active patterns may be electrically connected to the initialization voltage line.

According to some embodiments, the first conductive layer may further includes a second data line extending in the first direction and spaced apart from the first data line in the second direction and a third data line extending in the first direction and spaced apart from the second data line in the second direction, the first switching active pattern may be electrically connected to the third data line, the second switching active pattern may be electrically connected to the first data line, and the third switching active pattern may be electrically connected to the second data line.

According to some embodiments, the second conductive layer may include a first control pattern partially overlapping the first lower conductive pattern and the first driving active pattern in a plan view and contacting the first capacitor conductive pattern, a second control pattern partially overlapping the second lower conductive pattern and the second driving active pattern in a plan view, contacting the second capacitor conductive pattern, and spaced apart from the first control pattern in the first direction, and a third control pattern partially overlapping the third lower conductive pattern and the third driving active pattern in a plan view, contacting the third capacitor conductive pattern, and spaced apart from the second control pattern in the first direction.

According to some embodiments, the first control pattern and the first driving active pattern may define a first driving transistor, the second control pattern and the second driving active pattern may define a second driving transistor, and the third control pattern and the third driving active pattern may define a third driving transistor.

According to some embodiments, the second conductive layer may further include a first scan line overlapping the first to third switching active patterns in a plan view and a second scan line partially overlapping the first to third driving active patterns in a plan view.

According to some embodiments, the first scan line may define a first switching transistor together with the first switching active pattern, define a second switching transistor together with the second switching active pattern, and define a third switching transistor together with the third switching active pattern, and the second scan line may define a first initialization transistor together with the first initialization active pattern, define a second initialization transistor together with the second initialization active pattern, and define a third initialization transistor together with the third initialization active pattern.

According to some embodiments, the third conductive layer may include a first anode electrode partially overlapping the first lower conductive pattern in a plan view, a second anode electrode partially overlapping the second lower conductive pattern in a plan view and spaced apart from the first anode electrode, and a third anode electrode partially overlapping the third lower conductive pattern in a plan view and spaced apart from the second anode electrode.

According to some embodiments, the first anode electrode may be spaced apart from at least a portion of the first capacitor conductive pattern in a plan view, the second anode electrode may be spaced apart from at least a portion of the second capacitor conductive pattern in a plan view, and the third anode electrode may be spaced apart from at least a portion of the third capacitor conductive pattern in a plan view.

According to some embodiments, the first anode electrode may contact the first driving active pattern, the second anode electrode may contact the second driving active pattern, and the third anode electrode may contact the third driving active pattern.

According to some embodiments, the display device may include a first conductive layer on a substrate, an active layer on the first conductive layer, and a second conductive layer on the active layer. The first conductive layer may include a lower conductive pattern and a capacitor conductive pattern spaced apart from each other in a plan view, the active layer may include a driving active pattern partially overlapping the lower conductive pattern and the capacitor conductive pattern in a plan view, and the second conductive layer may include a control pattern partially overlapping the lower conductive pattern and the driving active pattern in a plan view.

According to some embodiments, the driving active pattern and the control pattern may define a driving transistor, and the capacitor conductive pattern and the driving active pattern may define a storage capacitor. For example, a portion of the control pattern overlapping the driving active pattern may be a gate electrode of the driving transistor, a portion of the capacitor conductive pattern overlapping the driving active pattern may be a lower electrode of the storage capacitor, and a portion of the driving active pattern overlapping the capacitor conductive pattern may be an upper electrode of the storage capacitor.

Also, according to some embodiments, the control pattern may contact the capacitor conductive pattern through a contact hole. Accordingly, the capacitor conductive pattern may be connected to the gate electrode of the driving transistor through the control pattern.

As the capacitor conductive pattern connected to the gate electrode of the driving transistor is below the driving active pattern, the capacitor conductive pattern may not be exposed to an upper conductive layer (e.g., a common electrode).

Accordingly, generation of parasitic capacitance between the capacitor conductive pattern and the upper conductive layer may be prevented or reduced. For example, parasitic capacitance of the capacitor conductive pattern connected to the gate electrode of the driving transistor may be prevented or reduced. Accordingly, a separate shielding layer for preventing generation of parasitic capacitance may not be formed on the capacitor conductive pattern. Therefore, a resolution of the display device may not deteriorate. Accordingly, a display quality of the display device can be relatively improved.

It is to be understood that both the foregoing general description and the following detailed description are illustrative and explanatory and are intended to provide further explanation of some embodiments of the present disclosure as claimed.

### BRIEF DESCRIPTION OF THE DRAWINGS

Illustrative, non-limiting embodiments will be more clearly understood from the following detailed description taken in conjunction with the accompanying drawings.

FIG. 1 is a plan view illustrating a display device according to some embodiments.

FIG. 2 is a circuit diagram illustrating a pixel included in the display device of FIG. 1 according to some embodiments.

FIGS. 3 to 10 are layout views illustrating the pixel of FIG. 2 according to some embodiments.

FIG. 11 is a cross-sectional view taken along the line I-I′ of FIG. 10 according to some embodiments.

FIG. 12 is a cross-sectional view illustrating a display device according to some embodiments.

FIG. 13 is a cross-sectional view illustrating a display device according to some embodiments.

FIG. 14 is a cross-sectional view illustrating a display device according to some embodiments.

FIG. 15 is a cross-sectional view illustrating a display device according to some embodiments.

FIG. 16 is a cross-sectional view illustrating a display device according to some embodiments.

### DETAILED DESCRIPTION

Aspects of some embodiments according to the present disclosure will now be described more fully hereinafter with reference to the accompanying drawings, in which various embodiments are shown. This invention may however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

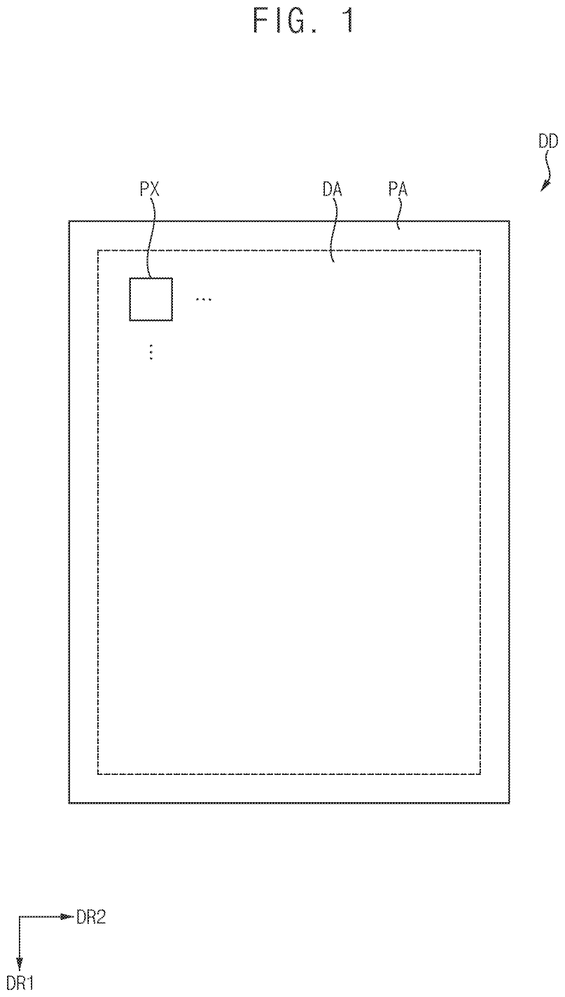

FIG. 1 is a plan view illustrating a display device according to some embodiments.

Referring to FIG. 1, a display device DD according to some embodiments may be divided into a display area DA and a peripheral area PA. The display area DA may display images, and the peripheral area PA may be located around (e.g., in a periphery or outside a footprint of) the display area DA. For example, the peripheral area PA may surround the display area DA.

According to some embodiments, the display device DD may have a rectangular shape in a plan view. However, embodiments according to the present invention are not necessarily limited thereto, and the display device DD may have various shapes in a plan view (e.g., a square, polygon, circle, etc.). In this case, a plane may be defined by the first direction DR1, and the second direction DR2 crossing the first direction DR1. For example, the second direction DR2 may be perpendicular to the first direction DR1.

The display device DD may include pixels PX located in the display area DA. For example, the pixels PX may be arranged in a matrix form along the first direction DR1 and the second direction DR2. Although FIG. 1 illustrates a single pixel PX, as a person having ordinary skill in the art would appreciate, a display device DD may include any suitable number of pixels PX according to the design of the display device DD.

A driver may be located in the peripheral area PA. The driver may provide signals and/or voltages to the pixels PX. For example, the driver may include a data driver and a gate driver.

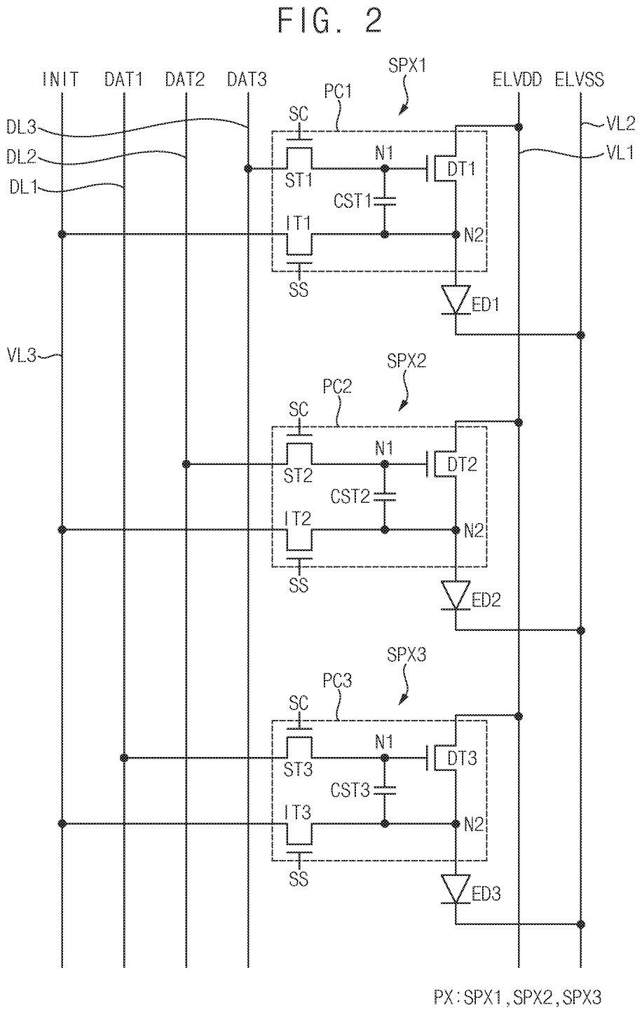

FIG. 2 is a circuit diagram illustrating a pixel included in the display device of FIG. 1.

Referring to FIG. 2, each of the pixels PX may include first to third sub-pixels SPX1, SPX2, and SPX3. As shown in FIG. 2, the first to third sub-pixels SPX1, SPX2, and SPX3 may have the same (or substantially the same) structure as each other. For example, each of the first to third sub-pixels SPX1, SPX2, and SPX3 may include a pixel circuit and a light emitting device electrically connected to the pixel circuit.

For example, the first sub-pixel SPX1 may include a first pixel circuit PC1 and a first light emitting device ED1, the second sub-pixel SPX2 may include a second pixel circuit PC2 and a second light emitting device ED2, and the third sub-pixel SPX3 may include a third pixel circuit PC3 and a third light emitting device ED3.

According to some embodiments, each of the first to third pixel circuits PC1, PC2, and PC3 may include a plurality of transistors and a capacitor. For example, the first sub-pixel SPX1 may include a first driving transistor DT1, a first switching transistor ST1, a first initialization transistor IT1, and a first storage capacitor CST1. The second sub-pixel SPX2 may include a second driving transistor DT2, a second switching transistor ST2, a second initialization transistor IT2, and a second storage capacitor CST2. The third sub-pixel SPX3 may include a third driving transistor DT3, a third switching transistor ST3, a third initialization transistor IT3, and a third storage capacitor CST3.

Hereinafter, a connection structure of the first sub-pixel SPX1 will be described in more detail.

In this case, as shown in FIG. 2, the second sub-pixel SPX2 and the third sub-pixel SPX3 may have substantially same connection structure as the first sub-pixel SPX1. Therefore, a description of the connection structure of the second sub-pixel SPX2 and the connection structure of the third sub-pixel SPX3 are replaced with a description of the connection structure of the first sub-pixel SPX1.

The first driving transistor DT1 may include a gate electrode connected to a first node N1, a first electrode receiving a driving power supply voltage ELVDD, and a second electrode connected to a second node N2. The first driving transistor DT1 may receive the driving power supply voltage ELVDD from a driving voltage line VL1 in response to a voltage of the first node N1 and supply a driving current to the first light emitting device ED1.

The first switching transistor ST1 may include a gate electrode receiving a first scan signal SC, a first electrode receiving a data signal (e.g., a third data signal DATA3), and a second electrode connected to the first node N1. The first switching transistor ST1 may be turned on by the first scan signal SC to electrically connect a data line (e.g., the third data line DL3) and the first node N1.

The first initialization transistor IT1 may include a gate electrode receiving a second scan signal SS, a first electrode connected to the second node N2, and a second electrode receiving an initialization voltage INIT. The first initialization transistor IT1 may be turned on by the second scan signal SS to electrically connect a initialization voltage line VL3 and the second node N2.

The first storage capacitor CST1 may be connected between the first node N1 and the second node N2. For example, the first storage capacitor CST1 may include a first electrode (e.g., a lower electrode) connected to the gate electrode of the first driving transistor DT1 and a second electrode (e.g., an upper electrode) connected to a first electrode (e.g., an anode) of the first light emitting device ED1.

The first light emitting device ED1 may include a first electrode (e.g., anode) connected to the second node N2 and a second electrode (e.g., cathode) receiving a common voltage ELVSS. The first light emitting device ED1 may emit light with a luminance corresponding to the driving current provided from the first pixel circuit PC1.

Meanwhile, in FIG. 2, the first to third driving transistors DT1, DT2, and DT3, the first to third switching transistors ST1, ST2, and ST3, and the first to third initialization transistors IT1, IT2, and IT3 are shown as n-channel metal oxide semiconductor (NMOS) transistors, embodiments according to the present disclosure are not necessarily limited thereto. For example, at least one of the plurality of transistors may be a p-channel metal oxide semiconductor (PMOS) transistor.

In addition, although one pixel circuit is illustrated as including three transistors and one capacitor in FIG. 2, embodiments according to the present disclosure are not necessarily limited thereto. For example, one pixel circuit may include four or more transistors or two or more capacitors.

In addition, although one sub-pixel is illustrated as including one light emitting device in FIG. 2, embodiments according to the present disclosure are not necessarily limited thereto. For example, one sub-pixel may include two or more light emitting devices.

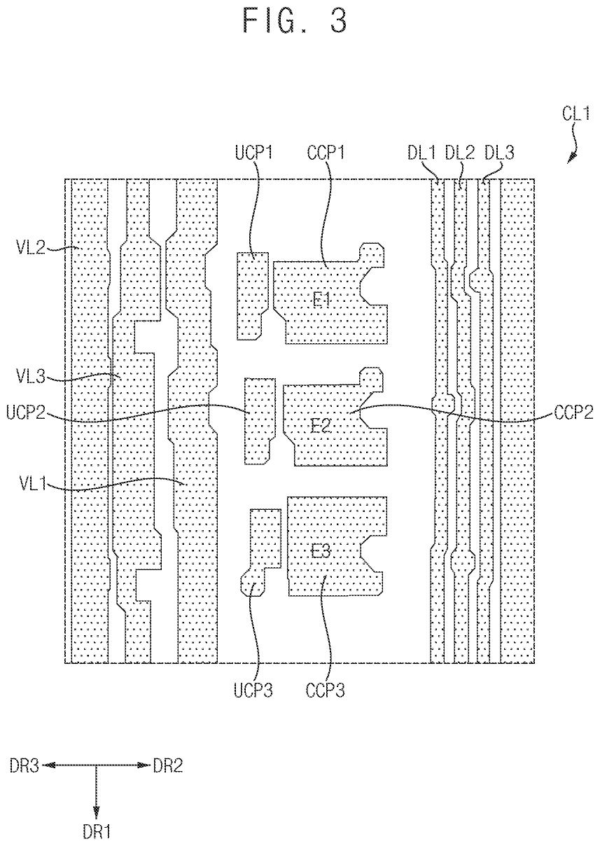

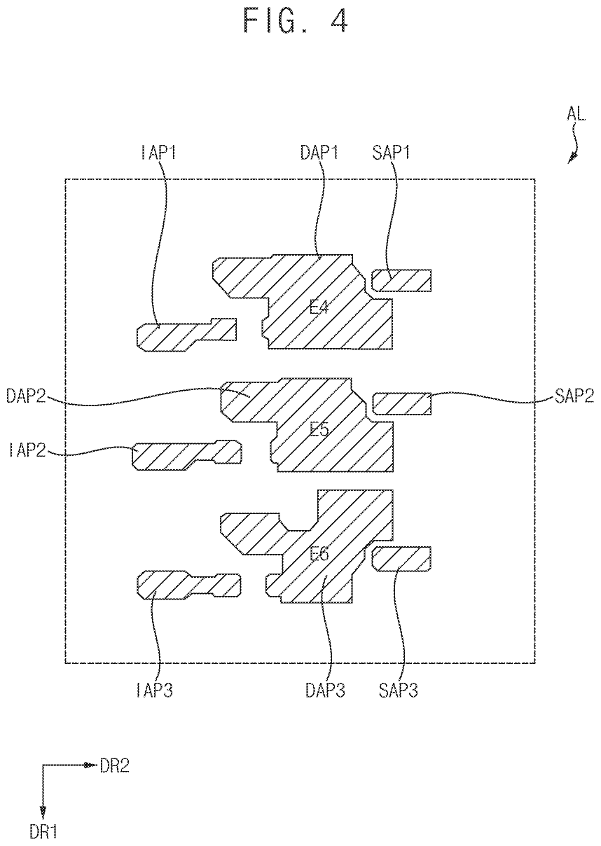

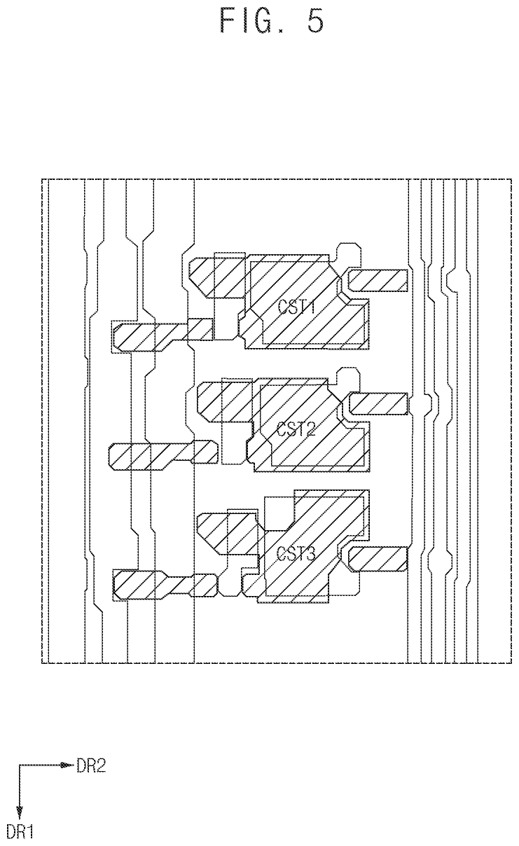

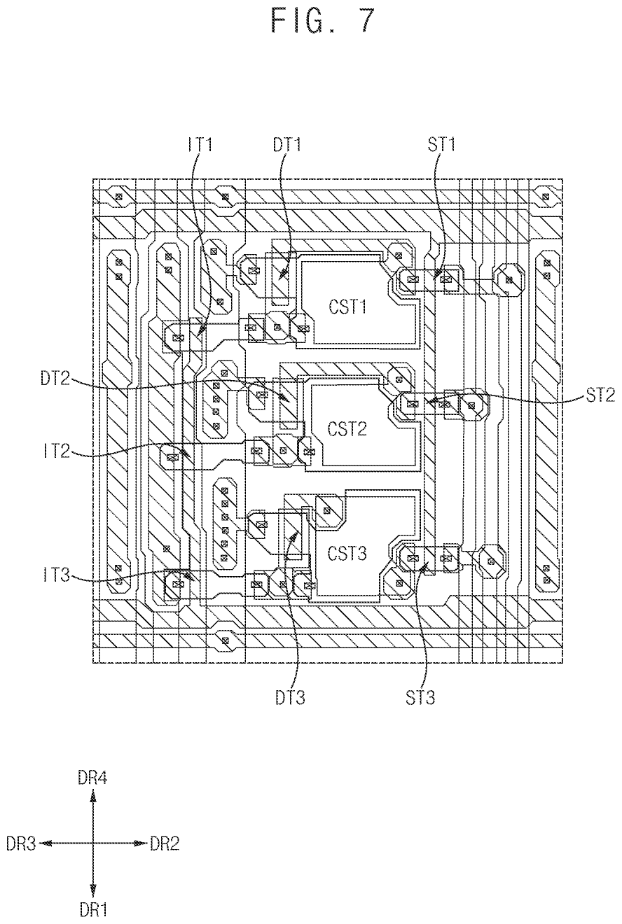

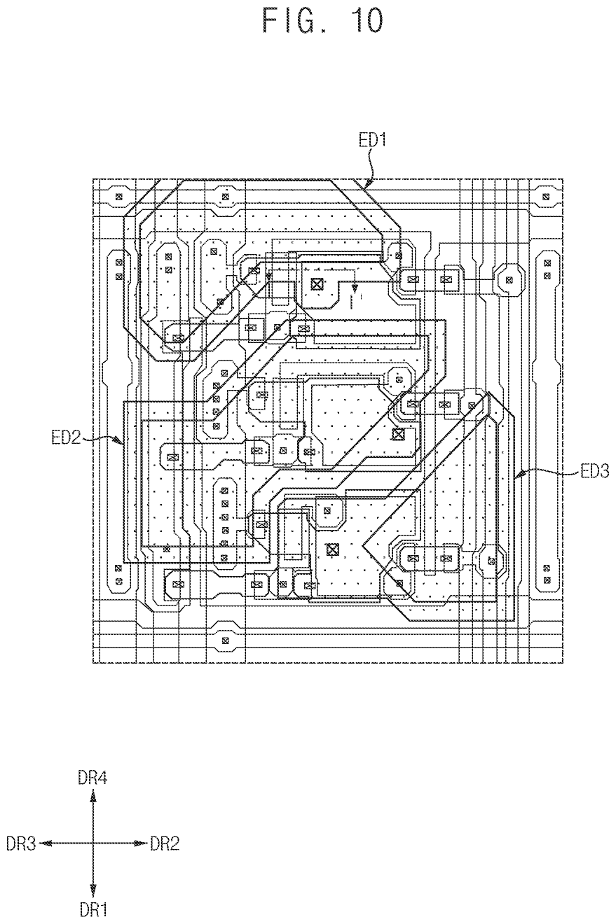

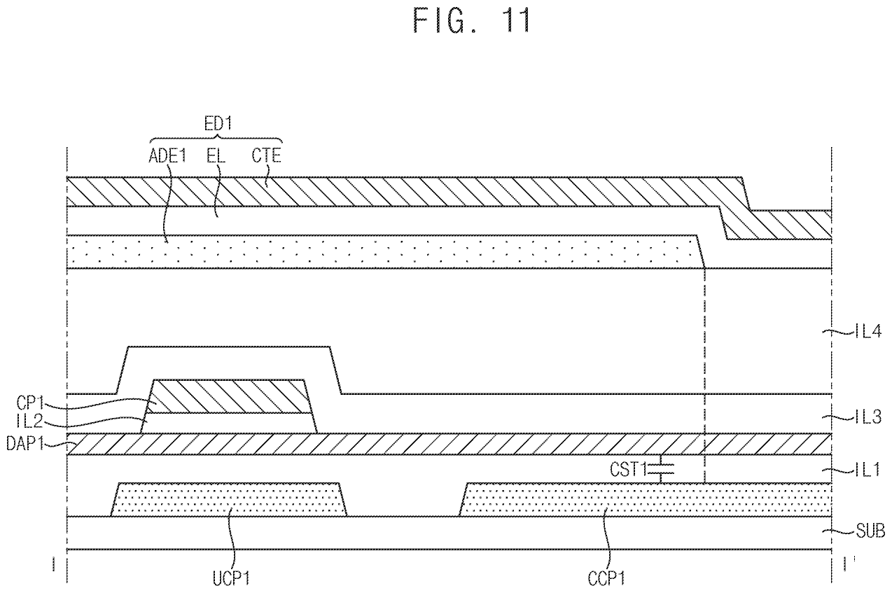

FIGS. 3 to 10 are layout views illustrating the pixel of FIG. 2. FIG. 11 is a cross-sectional view taken along the line-′ of FIG. 10.

Hereinafter, a structure of each layer of the pixel PX included in the display device DD will be described in more detail with reference to FIGS. 3 to 11.

Referring to FIGS. 2 and 3 to 11, according to some embodiments, each of the pixels PX included in the display device DD may include a first conductive layer CL1, an active layer AL, a second conductive layer CL2, a third conductive layer CL3, an emission layer EL, and a fourth conductive layer located on a substrate SUB.

The substrate SUB may include a transparent or opaque material. According to some embodiments, examples of materials that can be used as the substrate SUB may include glass, quartz, plastic, or the like. These may be used alone or in combination with each other.

As shown in FIGS. 3 and 11, the first conductive layer CL1 may be located on the substrate SUB. The first conductive layer CL1 may include a conductive material such as a metal, an alloy, a conductive metal nitride, a conductive metal oxide, or a transparent conductive material. Examples of the conductive material that can be used as the first conductive layer CL1 may include gold (Au), silver (Ag), aluminum (Al), platinum (Pt), nickel (Ni), titanium (Ti), palladium (Pd), magnesium (Mg), calcium (Ca), Lithium (Li), Chromium (Cr), Tantalum (Ta), Tungsten (W), Copper (Cu), Molybdenum (Mo), Scandium (Sc), Neodymium (Nd), Iridium (Ir), an alloy containing aluminum (Al), an alloy containing silver (Ag), an alloy containing copper (Cu), an alloy containing molybdenum (Mo), aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc oxide (IZO), or the like. These may be used alone or in combination with each other. The first conductive layer CL1 may have a single-layer structure or a multi-layer structure including a plurality of conductive layers.

The first conductive layer CL1 may include a driving voltage line VL1, a common voltage line VL2, an initialization voltage line VL3, first to third data lines DL1, DL2, and DL3, first to third lower conductive patterns UCP1, UCP2, and UCP3, and first to third capacitor conductive patterns CCP1, CCP2, and CCP3.

The driving voltage line VL1, the common voltage line VL2, the initialization voltage line VL3, the first to third data lines DL1, DL2, DL3, the first to third lower conductive patterns UCP1, UCP2, UCP3, and the first to third capacitor conductive patterns CCP1, CCP2, and CCP3 may be spaced apart from each other in a plan view.

The driving voltage line VL1 may extend in the first direction DR1. The driving power supply voltage ELVDD may be applied to the driving voltage line VL1.

The common voltage line VL2 may extend in the first direction DR1. The common voltage line VL2 may be spaced apart from the driving voltage line VL1 in a third direction DR3 opposite to the second direction DR2. The common voltage ELVSS may be applied to the common voltage line VL2.

The initialization voltage line VL3 may extend in the first direction DR1. The initialization voltage line VL3 may be spaced apart from the driving voltage line VL1 in the third direction DR3 and may be spaced apart from the common voltage line VL2 in the second direction DR2. That is, the initialization voltage line VL3 may be located between the driving voltage line VL1 and the common voltage line VL2. The initialization voltage INIT may be applied to the initialization voltage line VL3.

The first data line DL1 may extend in the first direction DR1. The first data line DL1 may be spaced apart from the driving voltage line VL1 in the second direction DR2. A first data signal DATA1 may be applied to the first data line DL1.

The second data line DL2 may extend in the first direction DR1. The second data line DL2 may be spaced apart from the first data line DL1 in the second direction DR2. A second data signal DATA2 may be applied to the second data line DL2.

The third data line DL3 may extend in the first direction DR1. The third data line DL3 may be spaced apart from the second data line DL2 in the second direction DR2. A third data signal DATA3 may be applied to the third data line DL3.

The first to third lower conductive patterns UCP1, UCP2, and UCP3 may be located between the driving voltage line VL1 and the first data line DL1. For example, the first to third lower conductive patterns UCP1, UCP2, and UCP3 may be spaced apart from the driving voltage line VL1 in the second direction DR2 and may be spaced apart from the first data line DL1 in the third direction DR3. According to some embodiments, the first to third lower conductive patterns UCP1, UCP2, and UCP3 may be spaced apart from each other along the first direction DR1.

The first to third capacitor conductive patterns CCP1, CCP2, and CCP3 may be located between the driving voltage line VL1 and the first data line DL1. For example, the first to third lower conductive patterns UCP1, UCP2, and UCP3 may be spaced apart from the driving voltage line VL1 in the second direction DR2 and may be spaced apart from the first data line DL1 in the third direction DR3.

For example, the first capacitor conductive pattern CCP1 may be located between the first lower conductive pattern UCP1 and the first data line DL1 in a plan view, and the second capacitor conductive pattern CCP2 may be located between the second lower conductive pattern UCP2 and the first data line DL1 in a plan view, and the third capacitor conductive pattern CCP3 may be located between the third lower conductive pattern UCP3 and the first data line DL1 in a plan view.

For example, the first capacitor conductive pattern CCP1 may be spaced apart from the first lower conductive pattern UCP1 in the second direction DR2 and may be spaced apart from the first data line DL1 in the third direction DR3. The second capacitor conductive pattern CCP2 may be spaced apart from the second lower conductive pattern UCP2 in the second direction DR2 and may be spaced apart from the first data line DL1 in the third direction DR3. The third capacitor conductive pattern CCP3 may be spaced apart from the third lower conductive pattern UCP3 in the second direction DR2 and may be spaced apart from the first data line DL1 in the third direction DR3.

In other words, the first lower conductive pattern UCP1 may be located between the driving voltage line VL1 and the first capacitor conductive pattern CCP1 in a plan view, and the second lower conductive pattern UCP2 may be located between the driving voltage line VL1 and the second capacitor conductive pattern CCP2, and the third lower conductive pattern UCP3 may be located between the driving voltage line VL1 and the third capacitor conductive pattern CCP3 in a plan view.

For example, the first lower conductive pattern UCP1 may be spaced apart from the driving voltage line VL1 in the second direction DR2 and may be spaced apart from the first capacitor conductive pattern CCP1 in the third direction DR3. The second lower conductive pattern UCP2 may be spaced apart from the driving voltage line VL1 in the second direction DR2 and may be spaced apart from the second capacitor conductive pattern CCP2 in the third direction DR3. The third lower conductive pattern UCP3 may be spaced apart from the driving voltage line VL1 in the second direction DR2 and may be spaced apart from the third capacitor conductive pattern CCP3 in the third direction DR3.

As shown in FIGS. 3, 4, 5 and 11, the active layer AL may be located on the first conductive layer CL1. The active layer AL may include an oxide semiconductor, a silicon semiconductor, or an organic semiconductor. For example, the oxide semiconductor may include at least one oxide of indium (In), gallium (Ga), tin (Sn), zirconium (Zr), vanadium (V), hafnium (Hf), cadmium (Cd), germanium (Ge), chromium (Cr), titanium (Ti), or zinc (Zn). The silicon semiconductor may include amorphous silicon, polycrystalline silicon, or the like.

According to some embodiments, a first insulating layer IL1 may be located between the first conductive layer CL1 and the active layer AL. The first insulating layer IL1 may block diffusion of impurities such as oxygen and moisture into the active layer AL through the substrate SUB. Also, the first insulating layer IL1 may provide a flat upper surface on the substrate SUB. The first insulating layer IL1 may include an inorganic insulating material such as a silicon compound or a metal oxide. Examples of the inorganic insulating material that can be used as the first insulating layer IL1 may include silicon oxide (SiO), silicon nitride (SiN), silicon oxynitride (SiON), silicon oxycarbide (SiOC), silicon carbonitride (SiCN), aluminum oxide (AlO), and aluminum nitride. (AlN), tantalum oxide (TaO), hafnium oxide (HfO), zirconium oxide (ZrO), titanium oxide (TiO), or the like. These may be used alone or in combination with each other. The first insulating layer IL1 may have a single-layer structure or a multi-layer structure including a plurality of insulating layers.

The active layer AL may include first to third driving active patterns DAP1, DAP2, and DAP3, first to third switching active patterns SAP1, SAP2, and SAP3, and first to third initialization active patterns IAP1, IAP2, and IAP3.

The first to third driving active patterns DAP1, DAP2, and DAP3, the first to third switching active patterns SAP1, SAP2, and SAP3, and the first to third initialization active patterns IAP1, IAP2, and IAP3 may be spaced apart from each other. For example, the first to third driving active patterns DAP1, DAP2, and DAP3 may be spaced apart from each other along the first direction DR1. The first to third switching active patterns SAP1, SAP2, and SAP3 may be spaced apart from each other along the first direction DR1. The first to third initialization active patterns IAP1, IAP2, and IAP3 may be spaced apart from each other along the first direction DR1.

The first driving active pattern DAP1 may partially overlap the first lower conductive pattern UCP1 and the first capacitor conductive pattern CCP1. That is, the first driving active pattern DAP1 may overlap at least a portion of the first lower conductive pattern UCP1 and at least a portion of the first capacitor conductive pattern CCP1.

A portion of the first capacitor conductive pattern CCP1 overlapping the first driving active pattern DAP1 may be a lower electrode E1 of the first storage capacitor CST1, and a portion of the first driving active pattern DAP1 overlapping the first capacitor conductive pattern CCP1 may be an upper electrode E4 of the first storage capacitor CST1. Accordingly, the first capacitor conductive pattern CCP1 and the first driving active pattern DAP1 may form the first storage capacitor CST1.

The second driving active pattern DAP2 may partially overlap the second lower conductive pattern UCP2 and the second capacitor conductive pattern CCP2. That is, the second driving active pattern DAP2 may overlap at least a portion of the second lower conductive pattern UCP2 and at least a portion of the second capacitor conductive pattern CCP2.

A portion of the second capacitor conductive pattern CCP2 overlapping the second driving active pattern DAP2 may be a lower electrode E2 of the second storage capacitor CST2, and a portion of the second driving active pattern DAP2 overlapping the second capacitor conductive pattern CCP2 may be an upper electrode E5 of the second storage capacitor CST2. Accordingly, the second capacitor conductive pattern CCP2 and the second driving active pattern DAP2 may form the second storage capacitor CST2.

The third driving active pattern DAP3 may partially overlap the third lower conductive pattern UCP3 and the third capacitor conductive pattern CCP3. That is, the third driving active pattern DAP3 may overlap at least a portion of the third lower conductive pattern UCP3 and at least a portion of the third capacitor conductive pattern CCP3.

A portion of the third capacitor conductive pattern CCP3 overlapping the third driving active pattern DAP3 may be a lower electrode E3 of the third storage capacitor CST3, and a portion of the third driving active pattern DAP3 overlapping the third capacitor conductive pattern CCP3 may be an upper electrode E6 of the third storage capacitor CST3. Accordingly, the third capacitor conductive pattern CCP3 and the third driving active pattern DAP3 may form the third storage capacitor CST3.

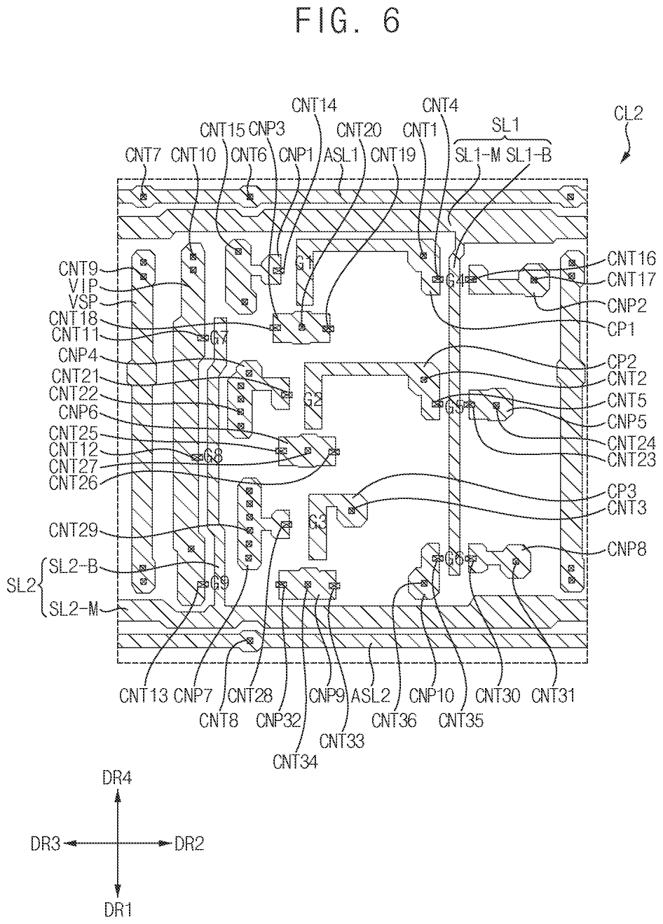

As shown in FIGS. 6, 7 and 11, the second conductive layer CL2 may be located on the active layer AL. The second conductive layer CL2 may include a conductive material such as a metal, an alloy, a conductive metal nitride, a conductive metal oxide, or a transparent conductive material. Examples of the conductive material that can be used as the second conductive layer CL2 may include gold (Au), silver (Ag), aluminum (Al), platinum (Pt), nickel (Ni), titanium (Ti), palladium (Pd), magnesium (Mg), calcium (Ca), Lithium (Li), Chromium (Cr), Tantalum (Ta), Tungsten (W), Copper (Cu), Molybdenum (Mo), Scandium (Sc), Neodymium (Nd), Iridium (Ir), an alloy containing aluminum (Al), an alloy containing silver (Ag), an alloy containing copper (Cu), an alloy containing molybdenum (Mo), aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc oxide (IZO), or the like. These may be used alone or in combination with each other.

A second insulating layer IL2 may be located between the active layer AL and the second conductive layer CL2. The second insulating layer IL2 may include an inorganic insulating material.

The second conductive layer CL2 may include first to third control patterns CP1, CP2, and CP3, a first scan line SL1, a second scan line SL2, a first auxiliary line ASL1, a second scan line SL1, a second auxiliary line ASL2, a common voltage auxiliary pattern VSP, initialization voltage auxiliary patterns VIP, and first to tenth connection patterns CNP1, CNP2, . . . , CNP9, CNP10.

The first to third control patterns CP1, CP2, and CP3, the first scan line SL1, the second scan line SL2, the first auxiliary line ASL1, the second scan line SL1, the second auxiliary line ASL2, the common voltage auxiliary pattern VSP, the initialization voltage auxiliary patterns VIP, and the first to tenth connection patterns CNP1, CNP2, . . . , CNP9, CNP10 may be spaced apart from each other in a plan view.

The first control pattern CP1 may partially overlap the first lower conductive pattern UCP1 and the first driving active pattern DAP1. A portion of the first control pattern CP1 overlapping the first lower conductive pattern UCP1 and the first driving active pattern DAP1 may be a gate electrode G1 of the first driving transistor DT1. Meanwhile, a portion of the first driving active pattern DAP1 overlapping the gate electrode G1 may be a channel portion of the first driving transistor DT1. Accordingly, the first driving active pattern DAP1 and the gate electrode G1 may form the first driving transistor DT1.

The first control pattern CP1 may contact the first capacitor conductive pattern CCP1 through a first contact hole CNT1. Accordingly, the first control pattern CP1 may be electrically connected to the first capacitor conductive pattern CCP1. Accordingly, the first capacitor conductive pattern CCP1 may be connected to the gate electrode G1 of the first driving transistor DT1 through the first control pattern CP1.

The second control pattern CP2 may partially overlap the second lower conductive pattern UCP2 and the second driving active pattern DAP2. A portion of the second control pattern CP2 overlapping the second lower conductive pattern UCP2 and the second driving active pattern DAP2 may be a gate electrode G2 of the second driving transistor DT2. Meanwhile, a portion of the second driving active pattern DAP2 overlapping the gate electrode G2 may be a channel portion of the second driving transistor DT2. Accordingly, the second driving active pattern DAP2 and the gate electrode G2 may form the second driving transistor DT2.

The second control pattern CP2 may contact the second capacitor conductive pattern CCP2 through a second contact hole CNT2. Accordingly, the second control pattern CP2 may be electrically connected to the second capacitor conductive pattern CCP2. Accordingly, the second capacitor conductive pattern CCP2 may be connected to the gate electrode G2 of the second driving transistor DT2 through the second control pattern CP2.

The third control pattern CP3 may partially overlap the third lower conductive pattern UCP3 and the third driving active pattern DAP3. A portion of the third control pattern CP3 overlapping the third lower conductive pattern UCP3 and the third driving active pattern DAP3 may be a gate electrode G3 of the third driving transistor DT3. Meanwhile, a portion of the third driving active pattern DAP3 overlapping the gate electrode G3 may be a channel portion of the third driving transistor DT3. Accordingly, the third driving active pattern DAP3 and the gate electrode G3 may form the third driving transistor DT3.

The third control pattern CP3 may contact the third capacitor conductive pattern CCP3 through a third contact hole CNT3. Accordingly, the third control pattern CP3 may be electrically connected to the third capacitor conductive pattern CCP3. Accordingly, the third capacitor conductive pattern CCP3 may be connected to the gate electrode G3 of the third driving transistor DT3 through the third control pattern CP3.

The first scan line SL1 may include a main portion SL1-M extending in the second direction DR2 and a branch portion SL1-B protruding and extending from the main portion SL1-M in the first direction DR1. The main portion SL1-M of the first scan line SL1 may be spaced apart from the first control pattern CP1 in a fourth direction DR4 opposite to the first direction DR1. The branch portion SL1-B of the first scan line SL1 may partially overlap the first to third switching active patterns SAP1, SAP2, and SAP3. The first scan signal SC may be applied to the first scan line SL1.

A portion of the first scan line SL1 overlapping the first switching active pattern SAP1 may be a gate electrode G4 of the first switching transistor ST1, a portion of the first scan line overlapping the second switching active pattern SAP2 may be a gate electrode G5 of the second switching transistor ST2, and a portion of the first scan line SL1 overlapping the third switching active pattern SAP3 may be a gate electrode G6 of the third switching transistor ST3.

Meanwhile, a portion of the first switching active pattern SAP1 overlapping the gate electrode G4 may be a channel portion of the first switching transistor ST1, a portion of the second switching active pattern SAP2 overlapping a gate electrode G5 may be a channel portion of the second switching transistor ST2, and a portion of the third switching active pattern SAP3 overlapping the gate electrode G6 may be a channel portion of the third switching transistor ST3.

Accordingly, the first switching active pattern SAP1 and the first scan line SL1 may form the first switching transistor ST1, the second switching active pattern SAP2 and the first scan line SL1 may form the second switching transistor ST2, and the third switching active pattern SAP3 and the first scan line SL1 may form the third switching transistor ST3.

According to some embodiments, the first control pattern CP1 may contact the first switching active pattern SAP1 through a fourth contact hole CNT4. Accordingly, the first switching active pattern SAP1 may be electrically connected to the first capacitor conductive pattern CCP1 through the first control pattern CP1.

The second control pattern CP2 may contact the second switching active pattern SAP2 through a fifth contact hole CNT5. Accordingly, the second switching active pattern SAP2 may be electrically connected to the second capacitor conductive pattern CCP2 through the second control pattern CP2.

The second scan line SL2 may include a main portion SL2-M extending in the second direction DR2 and a branch portion SL2-B protruding and extending from the main portion SL2-M in the fourth direction DR4. The main portion SL2-M of the second scan line SL2 may be spaced apart from the third control pattern CP3 in the first direction DR1. The branch portion SL-B of the second scan line SL2 may partially overlap the first to third initialization active patterns IAP1, IAP2, and IAP3. The second scan signal SS may be applied to the second scan line SL2.

A portion of the second scan line SL2 overlapping the first initialization active pattern IAP1 may be a gate electrode G7 of the first initialization transistor IT1, a portion of the second scan line SL2 overlapping the second initialization active pattern IAP2 may be a gate electrode G8 of the second initialization transistor IT2, and a portion of the second scan line SL2 overlapping the third initialization active pattern IAP3 may be a gate electrode G9 of the third initialization transistor IT3.

Meanwhile, a portion of the first initialization active pattern IAP1 overlapping the gate electrode G7 may be a channel portion of the first initialization transistor IT1, a portion of the second initialization active pattern IAP2 overlapping the gate electrode G8 may be a channel portion of the second initialization transistor IT2, and a portion of the third initialization active pattern IAP3 overlapping the gate electrode G9 may be a channel portion of the third initialization transistor IT3.

Accordingly, the first initialization active pattern IAP1 and the second scan line SL2 may form the first initialization transistor IT1, the second initialization active pattern IAP2 and the second scan line SL2 may form the second initialization transistor IT2, and the third initialization active pattern IAP3 and the second scan line SL2 may form the third initialization transistor IT3.

The first auxiliary line ASL1 may extend in the second direction DR2. The first auxiliary line ASL1 may be spaced apart from the first scan line SL1 in the fourth direction DR4. The first auxiliary line ASL1 may be electrically connected to the common voltage line VL2. For example, the first auxiliary line ASL1 may contact the common voltage line VL2 through a sixth contact hole CNT6 formed in the first insulating layer IL1 and the second insulating layer IL2.

According to some embodiments, the first auxiliary line ASL1 may also be electrically connected to the driving voltage line VL1. For example, the first auxiliary line ASL1 may contact the driving voltage line VL1 through a seventh contact hole CNT7 formed in the first insulating layer IL1 and the second insulating layer IL2.

The second auxiliary line ASL2 may extend in the second direction DR2. The second auxiliary line ASL2 may be spaced apart from the second scan line SL2 in the first direction DR1. The second auxiliary line ASL2 may be electrically connected to the driving voltage line VL1. For example, the second auxiliary line ASL2 may contact the common voltage line VL2 through a eighth contact hole CNT8 formed in the first and second insulating layers IL1 and IL2.

The common voltage auxiliary pattern VSP may be located between the main portion SL1-M of the first scan line SL1 and the main portion SL2-M of the second scan line SL2. For example, the common voltage auxiliary pattern VSP may be located on the common voltage line VL2. The common voltage auxiliary pattern VSP may be electrically connected to the common voltage line VL2. For example, the common voltage auxiliary pattern VSP may contact the common voltage line VL2 through ninth contact holes CNT9 formed in the first insulating layer IL1 and the second insulating layer IL2. The common voltage auxiliary pattern VSP may reduce resistance of the common voltage line VL2.

The initialization voltage auxiliary pattern VIP may be located between the main portion SL1-M of the first scan line SL1 and the main portion SL2-M of the second scan line SL2. For example, the initialization voltage auxiliary pattern VIP may be located on the initialization voltage line VL3. The initialization voltage auxiliary pattern VIP may be electrically connected to the initialization voltage line VL3. For example, the initialization voltage auxiliary pattern VIP may contact the initialization voltage line VL3 through tenth contact holes CNT10 formed in the first insulating layer IL1 and the second insulating layer IL2. The initialization voltage auxiliary pattern VIP may reduce the resistance of the initialization voltage line VL3.

According to some embodiments, the initialization voltage auxiliary pattern VIP may contact the first initialization active pattern IAP1 through a eleventh contact hole CNT11, contact the second initialization active pattern IAP2 through a twelfth contact hole CNT12, and contact the third initialization active pattern IAP3 through a thirteenth contact hole CNT13.

The first connection pattern CNP1 may contact the first driving active pattern DAP1 through a fourteenth contact hole CNT14 and contact the driving voltage line VL1 through a fifteenth contact hole CNT15. Accordingly, the first connection pattern CNP1 may electrically connect the first driving active pattern DAP1 and the driving voltage line VL1. The first driving transistor DT1 may be electrically connected to the driving voltage line VL1 through the first connection pattern CNP1.

The second connection pattern CNP2 may contact the first switching active pattern SAP1 through a sixteenth contact hole CNT16 and contact the third data line DL3 through a seventeenth contact hole CNT17. Accordingly, the second connection pattern CNP2 may electrically connect the first switching active pattern SAP1 and the third data line DL3. The first switching transistor ST1 may be electrically connected to the third data line DL3 through the second connection pattern CNP2.

The third connection pattern CNP3 may contact the first initialization active pattern IAP1 through a eighteenth contact hole CNT18 and contact the first driving active pattern DAP1 through a nineteenth contact hole CNT19. Meanwhile, the third connection pattern CNP3 may contact the first lower conductive pattern UCP1 through a twentieth contact hole CNT20.

The fourth connection pattern CNP4 may contact the second driving active pattern DAP2 through a twenty-first contact hole CNT21 and contact the driving voltage line VL1 through a twenty-second contact hole CNT22. Accordingly, the fourth connection pattern CNP4 may electrically connect the second driving active pattern DAP2 and the driving voltage line VL1. The second driving transistor DT2 may be electrically connected to the driving voltage line VL1 through the fourth connection pattern CNP4.

The fifth connection pattern CNP5 may contact the second switching active pattern SAP2 through a twenty-third contact hole CNT23 and contact the first data line DL1 through a twenty-fourth contact hole CNT24. Accordingly, the fifth connection pattern CNP5 may electrically connect the second switching active pattern SAP2 and the first data line DL1. The second switching transistor ST2 may be electrically connected to the first data line DL1 through the fifth connection pattern CNP5.

The sixth connection pattern CNP6 may contact the second initialization active pattern IAP2 through a twenty-fifth contact hole CNT25 and contact the second driving active pattern DAP2 through a twenty-sixth contact hole CNT26. Meanwhile, the sixth connection pattern CNP6 may contact the second lower conductive pattern UCP2 through a twenty-seventh contact hole CNT27.

The seventh connection pattern CNP7 may contact the third driving active pattern DAP3 through a twenty-eighth contact hole CNT28 and contact the driving voltage line VL1 through a twenty-ninth contact hole CNT29. Accordingly, the seventh connection pattern CNP7 may electrically connect the third driving active pattern DAP3 and the driving voltage line VL1. The third driving transistor DT3 may be electrically connected to the driving voltage line VL1 through the seventh connection pattern CNP7.

The eighth connection pattern CNP8 may contact the third switching active pattern SAP3 through a thirtieth contact hole CNT30 and contact the second data line DL2 through the thirty-first contact hole CNT31. Accordingly, the eighth connection pattern CNP8 may electrically connect the third switching active pattern SAP3 and the second data line DL2. The third switching transistor ST3 may be electrically connected to the second data line DL2 through the eighth connection pattern CNP8.

The ninth connection pattern CNP9 may contact the third initialization active pattern IAP3 through the thirty-second contact hole CNT32 and contact the third driving active pattern DAP3 through the thirty-third contact hole CNT33. Meanwhile, the ninth connection pattern CNP9 may contact the third lower conductive pattern UCP2 through a thirty-fourth contact hole CNT34.

The tenth connection pattern CNP10 may contact the third switching active pattern SAP3 through a thirty-fifth contact hole CNT35 and contact the third capacitor conductive pattern CCP3 through a thirty-sixth contact hole CNT36. Accordingly, the third switching active pattern SAP3 may be electrically connected to the third capacitor conductive pattern CCP3 through the tenth connection pattern CNP10.

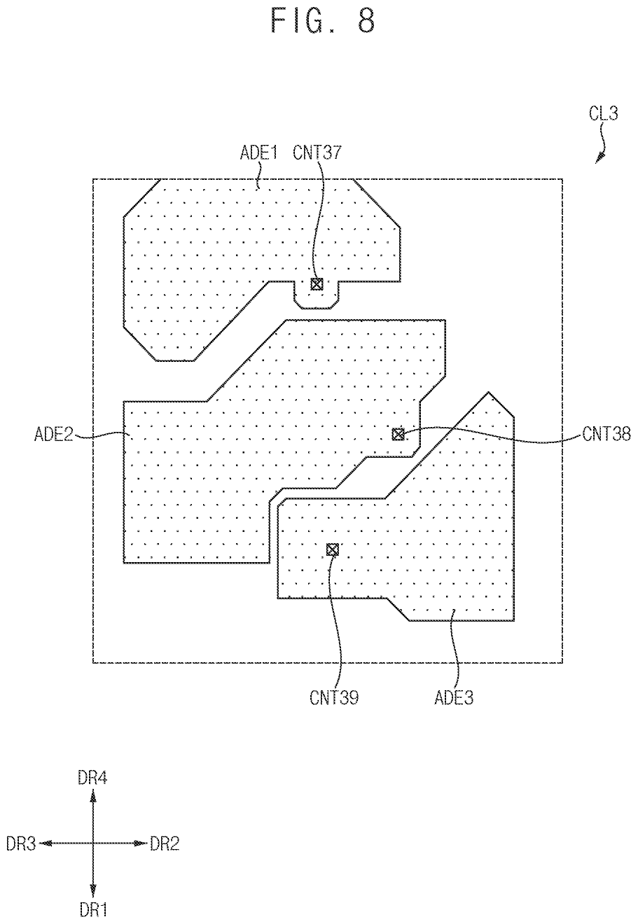

As shown in FIGS. 8, 9, and 11, the third conductive layer CL3 may be located on the second conductive layer CL2. The third conductive layer CL3 may include a conductive material such as a metal, an alloy, a conductive metal nitride, a conductive metal oxide, or a transparent conductive material. Examples of the conductive material that can be used as the third conductive layer CL3 may include gold (Au), silver (Ag), aluminum (Al), platinum (Pt), nickel (Ni), titanium (Ti), palladium (Pd), magnesium (Mg), calcium (Ca), Lithium (Li), Chromium (Cr), Tantalum (Ta), Tungsten (W), Copper (Cu), Molybdenum (Mo), Scandium (Sc), Neodymium (Nd), Iridium (Ir), an alloy containing aluminum (Al), an alloy containing silver (Ag), an alloy containing copper (Cu), an alloy containing molybdenum (Mo), aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc oxide (IZO), or the like. These may be used alone or in combination with each other.

A third insulating layer IL3 and a fourth insulating layer IL4 may be located between the second conductive layer CL2 and the third conductive layer CL3. The third insulating layer IL3 may include an inorganic insulating material. The fourth insulating layer IL4 may include an organic insulating material. In another example, the third insulating layer IL3 may be omitted.

The third conductive layer CL3 may include first to third anode electrodes ADE1, ADE2, and ADE3. The first to third anode electrodes ADE1, ADE2, and ADE3 may be spaced apart from each other in a plan view. The first anode electrode ADE1 may be the first electrode of the first light emitting device ED1, the second anode electrode ADE2 may be the first electrode of the second light emitting device ED2, and the third anode electrode ADE3 may be the first electrode of the third light emitting device ED3.

The first anode electrode ADE1 may contact the first driving active pattern DAP1 through a thirty-seventh contact hole CNT37. Accordingly, the first anode electrode ADE1 may be electrically connected to the first driving transistor DT1.

The first anode electrode ADE1 may be spaced apart from at least a portion of the first capacitor conductive pattern CCP1 in a plan view. That is, the first anode electrode ADE1 may not overlap at least a portion of the first capacitor conductive pattern CCP1 in a plan view.

The second anode electrode ADE2 may contact the second driving active pattern DAP2 through a thirty-eighth contact hole CNT38. Accordingly, the second anode electrode ADE2 may be electrically connected to the second driving transistor DT2.

The second anode electrode ADE2 may be spaced apart from at least a portion of the second capacitor conductive pattern CCP2 in a plan view. That is, the second anode electrode ADE2 may not overlap at least a portion of the second capacitor conductive pattern CCP2 in a plan view.

The third anode electrode ADE3 may contact the third driving active pattern DAP3 through a thirty-ninth contact hole CNT39. Accordingly, the third anode electrode ADE3 may be electrically connected to the third driving transistor DT3.

The third anode electrode ADE3 may be spaced apart from at least a portion of the third capacitor conductive pattern CCP3 in a plan view. That is, the third anode electrode ADE3 may not overlap at least a portion of the third capacitor conductive pattern CCP3 in a plan view.

A pixel definition layer may be located on the third conductive layer CL3. The pixel definition layer may define a pixel opening exposing at least a portion of each of the first to third anode electrodes ADE1, ADE2, and ADE3.

The emission layer EL may be located on the third conductive layer CL3 and the pixel definition layer. For example, the emission layer EL may be located on the first to third anode electrodes ADE1, ADE2, and ADE3 exposed by the pixel opening.

The fourth conductive layer may be located on the emission layer EL. For example, the fourth conductive layer may be entirely located on the display area DA of FIG. 1. The fourth conductive layer may be the second electrode of the first light emitting device ED1, the second electrode of the second light emitting device ED2, and the second electrode of the third light emitting device ED3. That is, the fourth conductive layer may be a common electrode CTE. As shown in FIG. 11, the first anode electrode ADE1, the emission layer EL, and the common electrode CTE may form the first light emitting device ED1, the second anode electrode ADE2, the emission layer EL, and the common electrode CTE may form the second light emitting device ED2, and the third anode electrode ADE3, the emission layer EL, and the common electrode CTE may form the third light emitting device ED3.

According to some embodiments, the display device DD may include the first conductive layer CL1 located on the substrate SUB, the active layer AL located on the first conductive layer CL1, and the second conductive layer CL2 located on the active layer AL. The first conductive layer CL1 may include a lower conductive pattern and a capacitor conductive pattern spaced apart from each other in a plan view, the active layer AL may include a driving active pattern partially overlapping the lower conductive pattern and the capacitor conductive pattern in a plan view, and the second conductive layer CL2 may include a control pattern partially overlapping the lower conductive pattern and the driving active pattern in a plan view.

The driving active pattern and the control pattern may define a driving transistor, and the capacitor conductive pattern and the driving active pattern may define a storage capacitor. For example, a portion of the control pattern overlapping the driving active pattern may be a gate electrode of the driving transistor, a portion of the capacitor conductive pattern overlapping the driving active pattern may be a lower electrode of the storage capacitor, and a portion of the driving active pattern overlapping the capacitor conductive pattern may be an upper electrode of the storage capacitor.

Also, the control pattern may contact the capacitor conductive pattern through a contact hole. Accordingly, the capacitor conductive pattern may be connected to the gate electrode of the driving transistor through the control pattern.

As the capacitor conductive pattern connected to the gate electrode of the driving transistor is located below the driving active pattern, the capacitor conductive pattern may not be exposed to an upper conductive layer (e.g., the common electrode). Accordingly, generation of parasitic capacitance between the capacitor conductive pattern and the upper conductive layer may be prevented or reduced. For example, parasitic capacitance of the capacitor conductive pattern connected to the gate electrode of the driving transistor may be prevented or reduced. Accordingly, a separate shielding layer for preventing generation of parasitic capacitance may not be formed on the capacitor conductive pattern. Therefore, a resolution of the display device DD may not deteriorate. Accordingly, display quality of the display device DD may be improved.

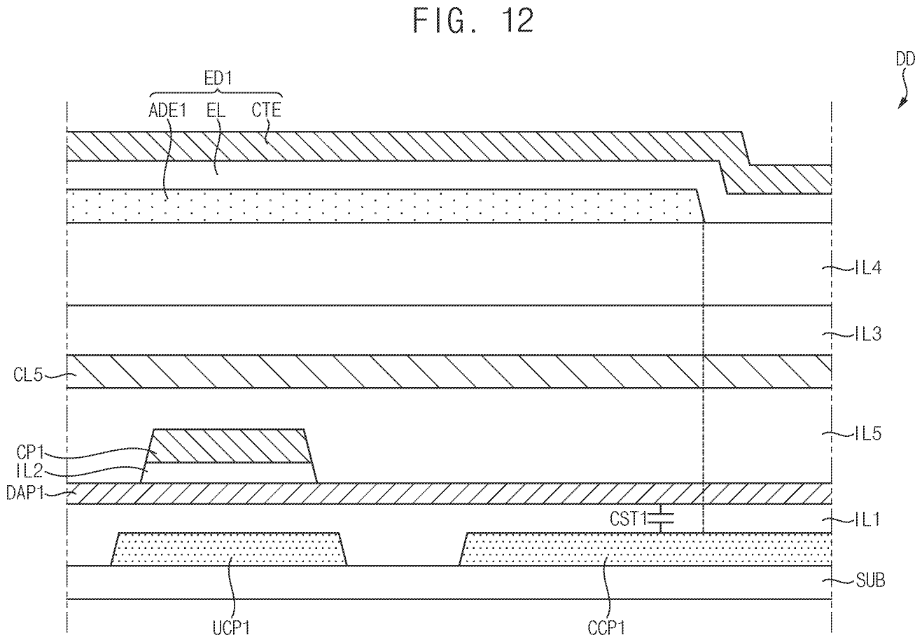

FIG. 12 is a cross-sectional view illustrating a display device according to some embodiments. For example, FIG. 12 may correspond to a cross-sectional view of FIG. 11.

Referring to FIG. 12, a display device DD1 according to some embodiments may be the same (or substantially the same) as the display device DD described with reference to FIGS. 1 to 11 except for a fifth insulating layer IL5 and a fifth conductive layer CL5. Therefore, some redundant descriptions may be omitted or simplified.

According to some embodiments, the display device DD1 may include the fifth conductive layer CL5. The fifth conductive layer CL5 may be located between the second conductive layer CL2 and the third conductive layer CL3. That is, the fifth conductive layer CL5 may be located above the second conductive layer CL2 and below the third conductive layer CL3.

The fifth conductive layer CL5 may include a conductive material such as a metal, an alloy, a conductive metal nitride, a conductive metal oxide, or a transparent conductive material. Examples of the conductive material that can be used as The fifth conductive layer CL5 may include gold (Au), silver (Ag), aluminum (Al), platinum (Pt), nickel (Ni), titanium (Ti), palladium (Pd), magnesium (Mg), calcium (Ca), Lithium (Li), Chromium (Cr), Tantalum (Ta), Tungsten (W), Copper (Cu), Molybdenum (Mo), Scandium (Sc), Neodymium (Nd), Iridium (Ir), an alloy containing aluminum (Al), an alloy containing silver (Ag), an alloy containing copper (Cu), an alloy containing molybdenum (Mo), aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc oxide (IZO), or the like. These may be used alone or in combination with each other.

The fifth insulating layer IL5 may be located between the second conductive layer CL2 and the fifth conductive layer CL5. The fifth insulating layer IL5 may include an inorganic insulating material. The third insulating layer IL3 and the fourth insulating layer IL4 may be located between the fifth conductive layer CL5 and the third conductive layer CL3. In another example, the third insulating layer IL3 may be omitted.

According to some embodiments, the fifth conductive layer CL5 may overlap at least a portion of each of the first to third lower conductive patterns UCP1, UCP2, and UCP3 (see in FIG. 3) and the first to third capacitor conductive patterns CCP1, CCP2, and CCP3 (see in FIG. 3) in a plan view. For example, the fifth conductive layer CL5 may overlap the first to third lower conductive patterns UCP1, UCP2, and UCP3 and the first to third capacitor conductive patterns CCP1, CCP2, and CCP3 in a plan view.

As the first to third capacitor conductive patterns CCP1, CCP2, and CCP3 are located under the fifth conductive layer CL5, the first to third capacitor conductive patterns CCP1, CCP2, and CCP3 may also be shielded by the conductive layer CL5. Accordingly, generation of parasitic capacitance between the capacitor conductive pattern and the upper conductive layer (e.g., the common electrode CTE) may be further prevented or reduced.

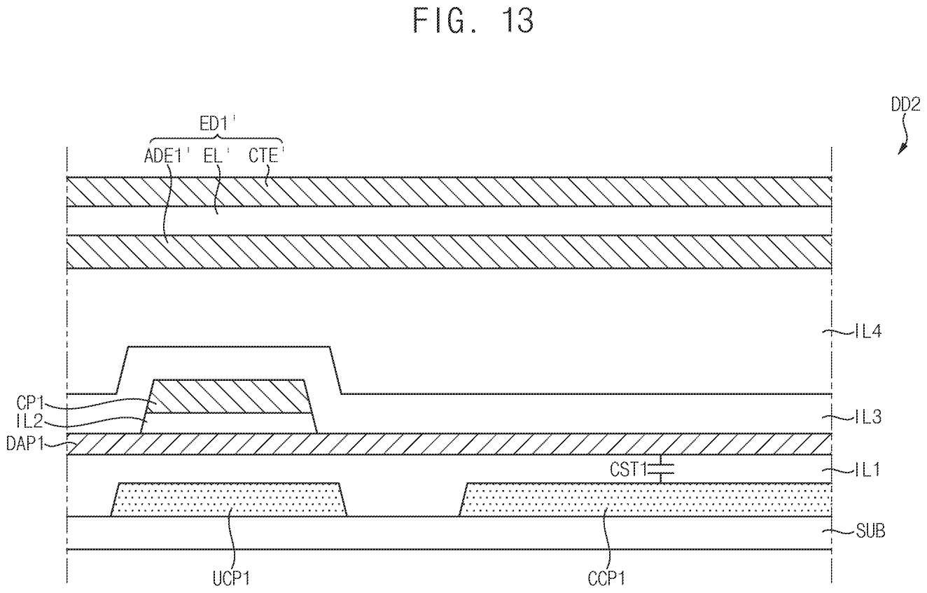

FIG. 13 is a cross-sectional view illustrating a display device according to some embodiments. For example, FIG. 13 may correspond to a cross-sectional view of FIG. 11.

Referring to FIG. 13, a display device DD2 according to some embodiments may be the same (or substantially the same) as the display device DD described with reference to FIGS. 1 to 11 except for a structure of a light emitting device. Therefore, some redundant descriptions may be omitted or simplified.

According to some embodiments, the first anode electrode ADE1′ may entirely overlap the first capacitor conductive pattern CCP1 in a plan view. That is, a portion of the first anode electrode ADE1′ may be entirely located between the first capacitor conductive pattern CCP1 and the common electrode CTE′.

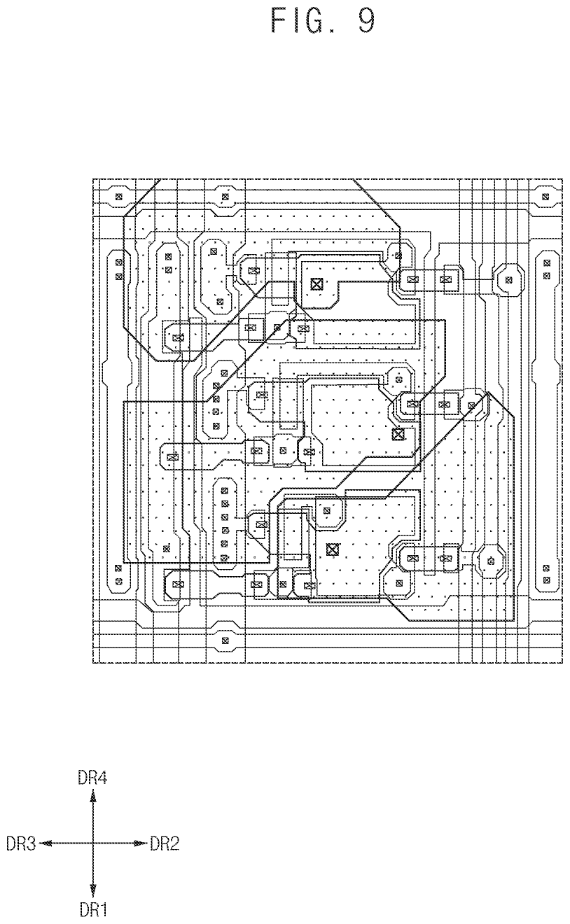

Meanwhile, according to some embodiments, the second anode electrode ADE2 (see in FIGS. 8 and 9) may entirely overlap the second capacitor conductive pattern CCP2 (see in FIGS. 8 and 9) in a plan view, and the third anode electrode ADE3 (see in FIGS. 8 and 9) may entirely overlap the third capacitor conductive pattern CCP3 (see in FIGS. 8 and 9) in a plan view.

As the first to third capacitor conductive patterns CCP1, CCP2, and CCP3 are entirely located under the anode electrodes, the first to third capacitor conductive patterns CCP1, CCP2, and CCP3 may be shielded by the anode electrodes. Accordingly, generation of parasitic capacitance between the capacitor conductive pattern and the upper conductive layer (e.g., the common electrode CTE) may be further prevented or reduced.

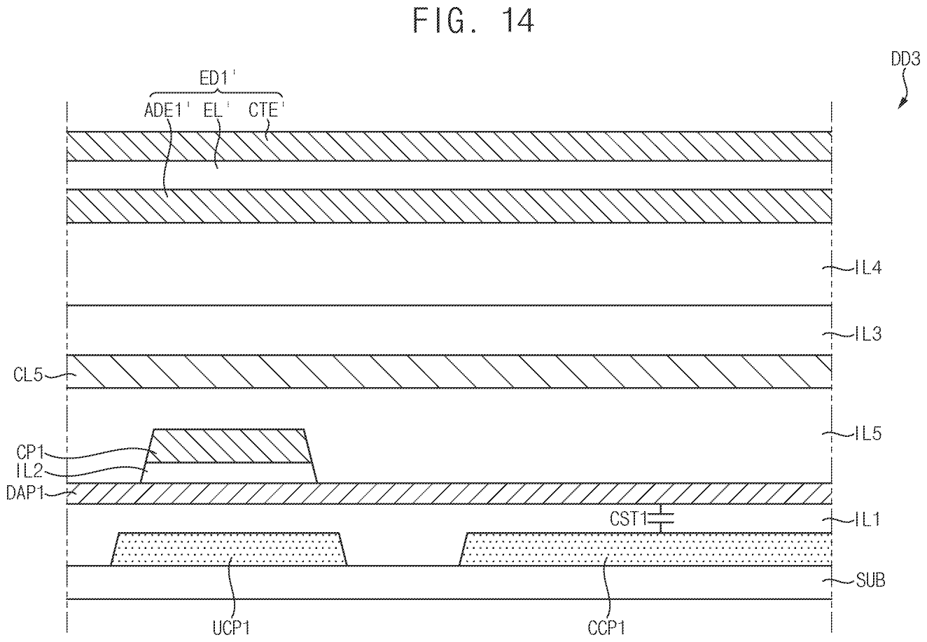

FIG. 14 is a cross-sectional view illustrating a display device according to some embodiments. For example, FIG. 14 may correspond to a cross-sectional view of FIG. 12.

Referring to FIG. 14, a display device DD3 according to some embodiments may be the same (or substantially the same) as the display device DD1 described with reference to FIG. 12 except for a structure of a light emitting device. Therefore, some redundant descriptions may be omitted or simplified.

According to some embodiments, even when the display device further includes a fifth conductive layer CL5 , the first anode electrode ADE1′ may entirely overlap the first capacitor conductive pattern CCP1 in a plan view.

Similarly, according to some embodiments, the second anode electrode ADE2 (see in FIGS. 8 and 9) may entirely overlap the second capacitor conductive pattern CCP2 (see in FIGS. 8 and 9) in a plan view, and the third anode electrode ADE3 (see in FIGS. 8 and 9) may entirely overlap the third capacitor conductive pattern CCP3 (see in FIGS. 8 and 9) in a plan view.

As the first to third capacitor conductive patterns CCP1, CCP2, and CCP3 are entirely located under the anode electrodes and the fifth conductive layer CL5, the first to third capacitor conductive patterns CCP1, CCP2, and CCP3 may be shielded by the anode electrodes and the fifth conductive layer CL5. Accordingly, generation of parasitic capacitance between the capacitor conductive pattern and the upper conductive layer (e.g., the common electrode CTE) may be further prevented or reduced.

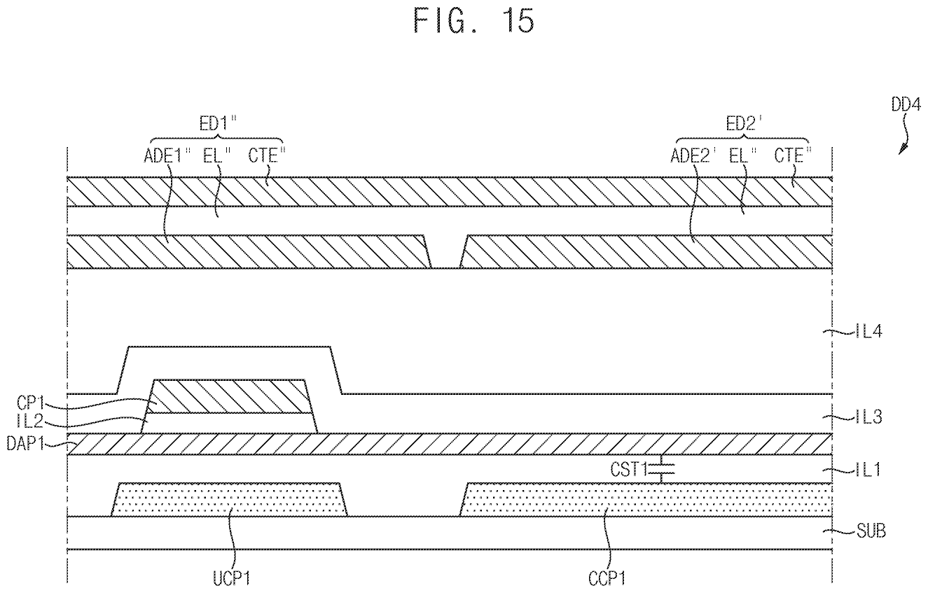

FIG. 15 is a cross-sectional view illustrating a display device according to some embodiments. For example, FIG. 15 may correspond to a cross-sectional view of FIG. 11.

Referring to FIG. 15, a display device DD4 according to some embodiments may be the same (or substantially the same) as the display device DD described with reference to FIGS. 1 to 11 except for a structure of a light emitting device. Therefore, some redundant descriptions may be omitted or simplified.

According to some embodiments, any one of the anode electrodes other than the first anode electrode ADE1″ included in the first light emitting device ED1″ may overlap the first capacitor conductive pattern CCP1 in a plan view.

For example, as shown in FIG. 15, a portion of the second anode electrode ADE2′ may overlap the first capacitor conductive pattern CCP1 in a plan view. That is, a portion of the second anode electrode ADE2′ may be entirely located between the first capacitor conductive pattern CCP1 and the common electrode CTE″. However, the present invention is not necessarily limited thereto.

Meanwhile, according to some embodiments, one of the anode electrodes other than the second anode electrode ADE2′′ included in the second light emitting device ED2′ may overlap the second capacitor conductive pattern CCP2 in a plan view, and one of the anode electrodes other than the third anode electrode ADE3 (see in FIGS. 8 and 9) included in the third light emitting device ED3 (see in FIG. 10) may overlap the third capacitor conductive pattern CCP3 in a plan view.

As the first to third capacitor conductive patterns CCP1, CCP2, and CCP3 are entirely located under the anode electrodes, the first to third capacitor conductive patterns CCP1, CCP2, and CCP3 may be shielded by the anode electrodes. Accordingly, generation of parasitic capacitance between the capacitor conductive pattern and the upper conductive layer (e.g., the common electrode CTE) may be further prevented or reduced.

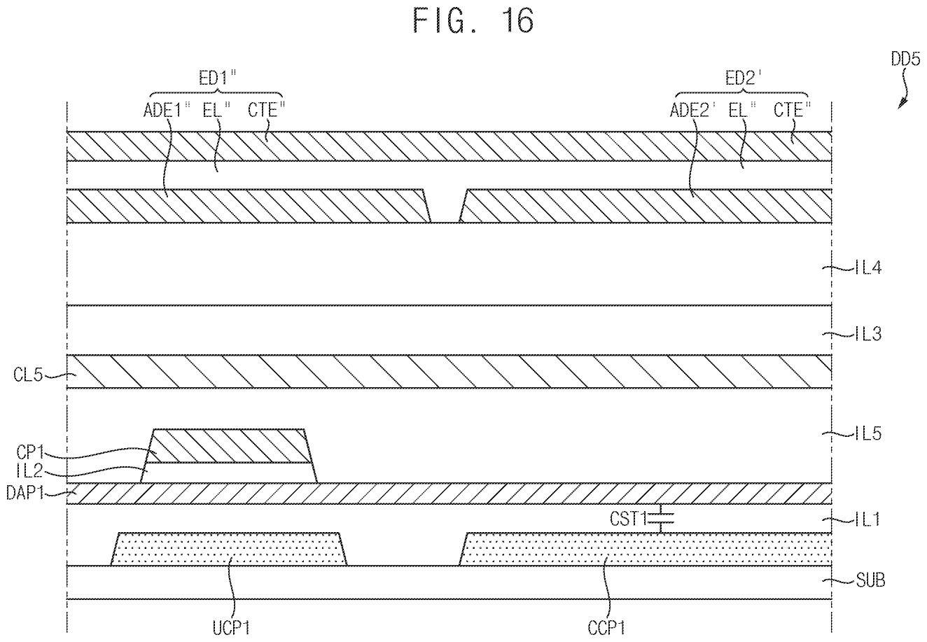

FIG. 16 is a cross-sectional view illustrating a display device according to some embodiments. For example, FIG. 16 may correspond to a cross-sectional view of FIG. 12.

Referring to FIG. 16, a display device DD5 according to some embodiments may be the same (or substantially the same) as the display device DD1 described with reference to FIG. 12 except for a structure of a light emitting device. Therefore, some redundant descriptions may be omitted or simplified.

According to some embodiments, even when the display device further includes the fifth conductive layer CL5, any one of the anode electrodes other than the first anode electrode ADE1′′ included in the first light emitting device ED1′′ may overlap the first capacitor conductive pattern CCP1 in a plan view.

For example, as shown in FIG. 16, a portion of the second anode electrode ADE2′ may overlap the first capacitor conductive pattern CCP1 in a plan view. That is, a portion of the second anode electrode ADE2′ may be entirely located between the first capacitor conductive pattern CCP1 and the common electrode CTE″. However, the present invention is not necessarily limited thereto.

Similarly, according to some embodiments, a one of the anode electrodes other than the second anode electrode ADE2′′ included in the second light emitting device ED2′ may overlap the second capacitor conductive pattern CCP2 in a plan view, and one of the anode electrodes other than the third anode electrode ADE3 (see in FIGS. 8 and 9) included in the third light emitting device ED3 (see in FIG. 10) may overlap the third capacitor conductive pattern CCP3 in a plan view.

As the first to third capacitor conductive patterns CCP1, CCP2, and CCP3 are entirely located under the anode electrodes and the fifth conductive layer CL5, the first to third capacitor conductive patterns CCP1, CCP2, and CCP3 may be shielded by the anode electrodes and the fifth conductive layer CL5. Accordingly, generation of parasitic capacitance between the capacitor conductive pattern and the upper conductive layer (e.g., the common electrode CTE) may be further prevented or reduced.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to aspects of some embodiments thereof, it will be understood by those of ordinary skill in the art that various changes in form and details may be made therein without departing from the spirit or scope of the invention as defined by the following claims, and their equivalents.

What is claimed is:

1. A display device comprising:
a substrate;
a first conductive layer on the substrate and including a lower conductive pattern and a capacitor conductive pattern spaced apart from the lower conductive pattern in a plan view;
an active layer on the first conductive layer, partially overlapping the lower conductive pattern and the capacitor conductive pattern in the plan view, and including a driving active pattern defining a storage capacitor together with the capacitor conductive pattern;
a second conductive layer on the active layer, partially overlapping the lower conductive pattern and the driving active pattern in the plan view, and including a control pattern defining a driving transistor together with the driving active pattern; and
a third conductive layer on the second conductive layer and including an anode electrode partially overlapping the lower conductive pattern in the plan view.

2. The display device of claim 1, wherein the control pattern contacts the capacitor conductive pattern.

3. The display device of claim 1, wherein the anode electrode is spaced apart from at least a portion of the capacitor conductive pattern in the plan view.

4. The display device of claim 1, wherein the anode electrode contacts the driving active pattern.

5. The display device of claim 1, wherein the first conductive layer further includes:
a driving voltage line extending in a first direction and electrically connected to the driving active pattern;
a data line extending in the first direction and spaced apart from the driving voltage line in a second direction crossing the first direction; and
an initialization voltage line extending in the first direction and spaced apart from the driving voltage line in a third direction opposite to the second direction.

6. The display device of claim 5, wherein the lower conductive pattern and the capacitor conductive pattern are located between the driving voltage line and the data line in the plan view.

7. The display device of claim 6, wherein the lower conductive pattern is located between the driving voltage line and the capacitor conductive pattern in the plan view, and
the capacitor conductive pattern is located between the lower conductive pattern and the data line in the plan view.

8. The display device of claim 5, wherein the active layer further includes:
a switching active pattern spaced apart from the driving active pattern in the plan view and electrically connected to the data line; and
an initialization active pattern spaced apart from the driving active pattern in the plan view and electrically connected to the initialization voltage line.

9. The display device of claim 8, wherein the second conductive layer further includes:
a first scan line partially overlapping the switching active pattern in the plan view; and
a second scan line partially overlapping the initialization active pattern in the plan view.

10. The display device of claim 9, wherein the switching active pattern and the first scan line define a switching transistor, and
the initialization active pattern and the second scan line define an initialization transistor.

11. The display device of claim 10, wherein the switching transistor is electrically connected to the capacitor conductive pattern.

12. The display device of claim 1, further comprising:
a fourth conductive layer between the second conductive layer and the third conductive layer and overlapping at least a portion of each of the lower conductive pattern and the capacitor conductive pattern in the plan view.

13. A display device comprising:
a substrate, a first conductive layer on the substrate, an active layer on the first conductive layer, a second conductive layer on the active layer, and a third conductive layer on the second conductive layer, and
wherein the first conductive layer includes:
a driving voltage line on the substrate and extending in a first direction;
a first data line on the substrate, extending in the first direction, and spaced apart from the driving voltage line in a second direction crossing the first direction;
an initialization voltage line on the substrate, extending in the first direction, and spaced apart from the driving voltage line in a third direction opposite to the second direction;
first to third lower conductive patterns on the substrate, located between the driving voltage line and the first data line in a plan view, and spaced apart from each other along the first direction; and
first to third conductive patterns on the substrate, located between the driving voltage line and the first data line in the plan view, and spaced apart from the first to third lower conductive patterns, and spaced apart from each other along the first direction.

14. The display device of claim 13, wherein a conductive pattern of a first capacitor is located between the first lower conductive pattern and the first data line in the plan view,
a conductive pattern of a second capacitor is located between the second lower conductive pattern and the first data line in the plan view, and
a conductive pattern of a third capacitor is located between the third lower conductive pattern and the first data line in the plan view.

15. The display device of claim 13, wherein the active layer includes:
a first driving active pattern partially overlapping the first lower conductive pattern and a conductive pattern of a first capacitor in the plan view;
a second driving active pattern partially overlapping the second lower conductive pattern and a conductive pattern of a second capacitor in the plan view and spaced apart from the first driving active pattern in the first direction;
a third driving active pattern partially overlapping the third lower conductive pattern and the conductive pattern of a third capacitor in the plan view and spaced apart from the second driving active pattern in the first direction;
first to third switching active patterns spaced apart from the first to third driving active patterns in the plan view and spaced apart from each other along the first direction; and
first to third initialization active patterns spaced apart from the first to third driving active patterns and the first to third switching active patterns in the plan view and spaced apart from each other along the first direction.

16. The display device of claim 15, wherein the first driving active pattern defines a first storage capacitor together with the conductive pattern of the first capacitor,
the second driving active pattern defines a second storage capacitor together with the conductive pattern of the second capacitor, and
the third driving active pattern defines a third storage capacitor together with the conductive pattern of the third capacitor.

17. The display device of claim 15, wherein the first to third driving active patterns are electrically connected to the driving voltage line, and
the first to third initialization active patterns are electrically connected to the initialization voltage line.

18. The display device of claim 15, wherein the first conductive layer further includes:
a second data line extending in the first direction and spaced apart from the first data line in the second direction; and
a third data line extending in the first direction and spaced apart from the second data line in the second direction,
the first switching active pattern is electrically connected to the third data line,
the second switching active pattern is electrically connected to the first data line, and
the third switching active pattern is electrically connected to the second data line.

19. The display device of claim 15, wherein the second conductive layer includes:
a first control pattern partially overlapping the first lower conductive pattern and the first driving active pattern in the plan view and contacting the conductive pattern of the first capacitor;
a second control pattern partially overlapping the second lower conductive pattern and the second driving active pattern in the plan view, contacting the conductive pattern of the second capacitor, and spaced apart from the first control pattern in the first direction; and
a third control pattern partially overlapping the third lower conductive pattern and the third driving active pattern in the plan view, contacting the conductive pattern of the third capacitor, and spaced apart from the second control pattern in the first direction.

20. The display device of claim 19, wherein the first control pattern and the first driving active pattern define a first driving transistor,
the second control pattern and the second driving active pattern define a second driving transistor, and
the third control pattern and the third driving active pattern define a third driving transistor.

21. The display device of claim 19, wherein the second conductive layer further includes:
a first scan line overlapping the first to third switching active patterns in the plan view; and
a second scan line partially overlapping the first to third driving active patterns in the plan view.

22. The display device of claim 21, wherein the first scan line defines a first switching transistor together with the first switching active pattern, defines a second switching transistor together with the second switching active pattern, and defines a third switching transistor together with the third switching active pattern, and
the second scan line defines a first initialization transistor together with the first initialization active pattern, defines a second initialization transistor together with the second initialization active pattern, and defines a third initialization transistor together with the third initialization active pattern.

23. The display device of claim 15, wherein the third conductive layer includes:
a first anode electrode partially overlapping the first lower conductive pattern in the plan view;
a second anode electrode partially overlapping the second lower conductive pattern in the plan view and spaced apart from the first anode electrode; and
a third anode electrode partially overlapping the third lower conductive pattern in the plan view and spaced apart from the second anode electrode.

24. The display device of claim 23, wherein the first anode electrode is spaced apart from at least a portion of the conductive pattern of the first capacitor in the plan view,
the second anode electrode is spaced apart from at least a portion of the conductive pattern of the second capacitor in the plan view, and
the third anode electrode is spaced apart from at least a portion of the conductive pattern of the third capacitor in the plan view.

25. The display device of claim 23, wherein the first anode electrode contacts the first driving active pattern,
the second anode electrode contacts the second driving active pattern, and
the third anode electrode contacts the third driving active pattern.
